(19) United States
(12) Patent Application Publication
(10) Pub. No.: US 2013/0198586 A1
(43) Pub. Date: Aug. 1, 2013

(54) DATA STORAGE CONTROL APPARATUS, DATA STORAGE APPARATUS AND DATA STORAGE METHOD IN THE SAME

(71) Applicant: Hidetoshi KOIKE, Kodaira-shi (JP)

(72) Inventor: Hidetoshi KOIKE, Kodaira-shi (JP)

(73) Assignee: KABUSHIKI KAISHA TOSHIBA, Tokyo (JP)

(21) Appl. No.: 13/555,843

(22) Filed: Jul. 23, 2012

(30) Foreign Application Priority Data
Jan. 31, 2012 (JP) 2012-018760

(51) Int. Cl. G06F 12/16; G06F 11/10; H03M 13/05

(52) U.S. Cl. 714/763; 711/162; 711/E12.103; 714/E11.034

(57) ABSTRACT

According to one embodiment, a data storage control apparatus includes an interface module and a controller. The interface module receives first data, in specific units, from a host and stores the data in a buffer memory. The controller generates second data from the first data stored in the buffer memory, and performs a control to write the second data to a nonvolatile storage medium. The controller generates the second data of a second format having the same size as the first format of the data stored in an ordinary recording area provided at the nonvolatile storage medium, and including a plurality of units of the first data and invalid data. The controller further performs a control to write the second data in a save area provided on the nonvolatile storage medium.

### CROSS-REFERENCE TO RELATED APPLICATIONS

This application is based upon and claims the benefit of priority from prior Japanese Patent Application No. 2012-018760, filed Jan. 31, 2012, the entire contents of which are incorporated herein by reference.

### FIELD

Embodiments described herein relate generally to a data storage control apparatus, a data storage apparatus and a data storage method.

### BACKGROUND

In any data storage apparatus such as a hard disk drive (referred to as a disk drive in some cases hereinafter), the data transferred, in units of sectors, from a host is temporarily stored in a buffer memory and then transferred from the buffer memory to a disk that is a nonvolatile recording medium.

In recent years, disk drives have been developed, which use sector size larger (e.g., 4 K bytes each) than the sector size hitherto used (e.g., 512 bytes each), thereby to increase the storage capacity of the disk. More specifically, the error correction code (ECC) data added to each sector can be reduced to increase the user-data storage area. For convenience, the sector of the conventional sector size will be called a sub-sector (or short sector), and the sector of large sector size will be called a long sector.

In any disk drive of the long sector (or media sector) type, data of a long sector format is written to the disk. A disk drive of the long sector type is called a native 4K type if a host uses long sector format. If a host uses short sector format, however, the disk drive of the long sector type is called an emulation mode type and is distinguished from the first-mentioned long sector type.

To the disk drive of the emulation mode type, the host transfers data in sub-sector units (in short sector format) as hitherto been practiced. As a result, sub-sector data (i.e., partial sector data), smaller than long-sector data, increases in the buffer memory.

Therefore, the sector format must be changed in the buffer of the disk drive. That is, a sub-sector process is performed, changing the data to data in the long sector format and then transferring the data to the disk. More precisely, data in units of long sectors must be read from the disk and replaced by the data stored in the buffer memory in units of sub-sectors, and the data in units of sub-sectors must be written to the disk. This process is known as a read-modify-write (RMW) process.

In any disk drive of the long sector type (media sector type) in emulation mode, the RMW process is performed to change the sector format. To enhance the operating efficiency of the disk drive, the RMW process is better performed in, for example, the idling period when read/write commands are not executed at all. If the power supply is cut in the idling period, however, the data stored in the buffer memory in units of sub-sectors will be erased before it is written to the disk.

### BRIEF DESCRIPTION OF THE DRAWINGS

FIG. 1 is a block diagram explaining the configuration of a data storage apparatus according to an embodiment;

FIGS. 2A and 2B are diagrams explaining a disk and components peripheral to the disk, all according to the embodiment;

FIG. 3 is a diagram explaining the internal state of a buffer memory according to the embodiment;

FIG. 4 is a diagram explaining an exemplary arrangement of save areas on the disk according to the embodiment;

FIG. 5 is a diagram explaining another exemplary arrangement of save areas on the disk according to the embodiment;

FIGS. 6A and 6B are diagrams explaining the sector formats of the ordinary data area and a save area provided on the disk according to the embodiment;

FIG. 7 is a diagram explaining the format of a table used in the data transfer control performed in the embodiment;

FIG. 8 is a diagram showing an example of the table according to the embodiment;

FIG. 9 is a diagram explaining a CRC process performed at the save areas in the embodiment;

FIG. 10 is a diagram explaining an RMW process according to the embodiment; and

FIG. 11 is a flowchart explaining a data transfer control according to the embodiment.

### DETAILED DESCRIPTION

In general, according to one embodiment, a data storage control apparatus includes an interface module and a controller. The interface module receives first data, in specific units, from a host and stores the data in a buffer memory. The controller generates second data from the first data stored in the buffer memory, and performs a control to write the second data to a nonvolatile storage medium. The controller generates the second data of a second format having the same size as the first format of the data stored in an ordinary recording area provided at the nonvolatile storage medium, and including a plurality of units of the first data and invalid data. The controller further performs a control to write the second data in a save area provided on the nonvolatile storage medium.

An embodiment will be described hereinafter with reference to the accompanying drawings.

### (Configuration of the Data Storage Apparatus)

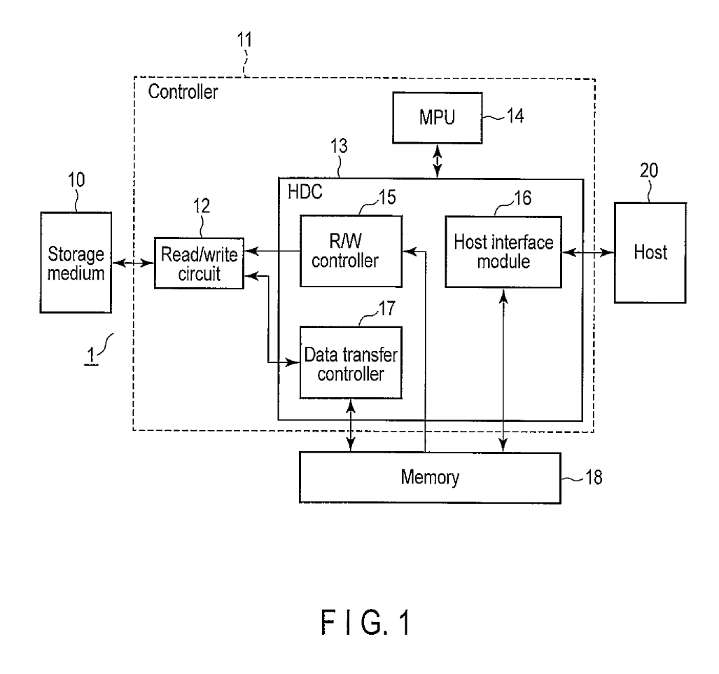

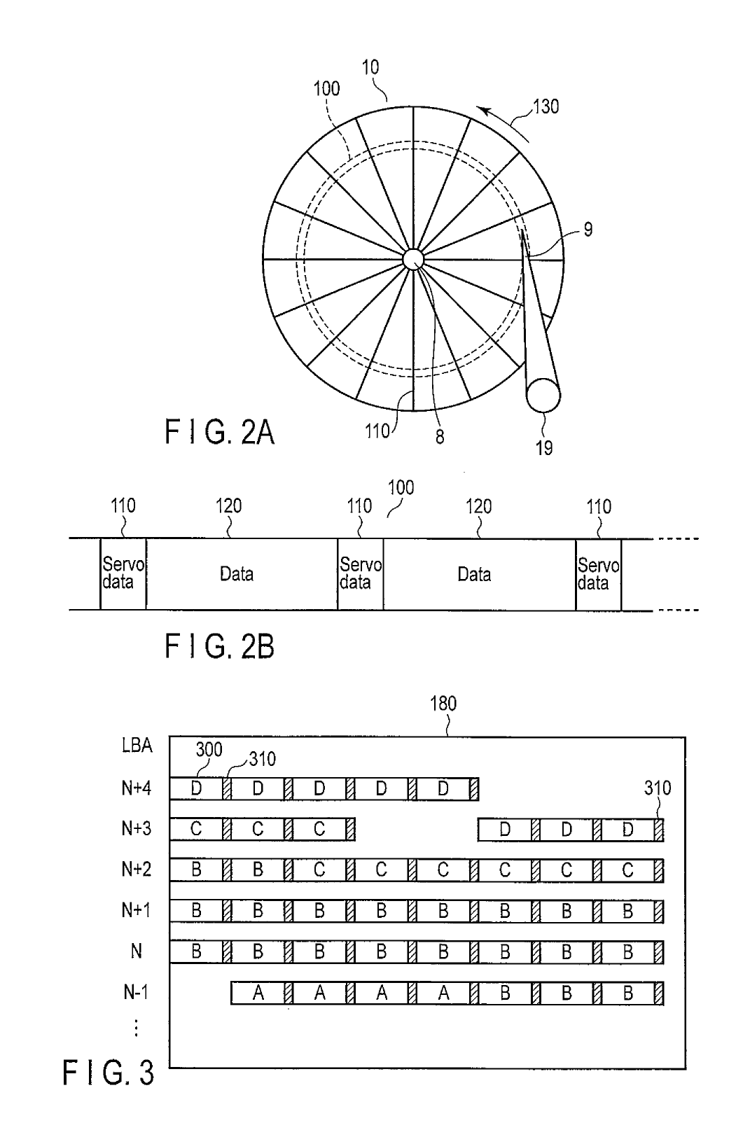

As FIG. 1 shows, a data storage apparatus 1 according to an embodiment includes a nonvolatile storage medium 10, a controller 11, and a memory 18, which are major components. The data storage apparatus 1 is a disk drive of the long sector type (media sector type). As shown in FIG. 2A, the nonvolatile storage medium 10 is a magnetic disk (hereinafter referred to as “disk”). The memory 18 is a dynamic random access memory (DRAM), a static random access memory (SRAM), or a flash memory, which is used as a buffer memory 180 (see FIG. 3) as will be described later.

The controller 11 includes a read/write circuit 12, a hard disk controller (HDC) 13, and a microprocessor (MPU) 14. The read/write (R/W) circuit 12 is also known as a read/write channel, and reads data from, and writes data to, the storage medium (disk) 10, under the control of the HDC 13. The MPU 14 cooperates with the HDC 13 to control the other components of the disk drive 1. More specifically, the MPU 14 performs servo control, executes read/write commands and performs an entry process with respect to a table (described later).

The HDC 13 includes a read/write (R/W) controller 15, a host interface module 16, and a data transfer controller 17. The R/W controller 15 generates sector pulses from the sector pulse control data stored in the memory 18. Further, the R/W controller 15 supplies a read/write gate to the R/W circuit 12, causing the R/W circuit 12 to read or write data. The host interface module 16 performs a transfer control, whereby data or commands transferred from a host 20 are received or the data read from the buffer memory 180 is transmitted to the host 20. Note that the host 20 is an interface module of, for example, the Serial ATA (SATA) standard which is included in a personal computer.

The data transfer controller 17 comprises hardware such as logic gates, and controls the data transfer between the buffer memory 180 and the R/W circuit 12. In this embodiment, the data transfer controller 17 first combines the data stored in the respective sub-sectors of the buffer memory 180 before subjecting the data to an RMW process, and then performs a process of converting the data to data of long sector format.

FIGS. 2A and 2B are diagrams explaining the disk 10 and the components peripheral to the disk 10.

As shown in FIG. 2A, a head 9 reads data from the disk 10 and writes data to the disk 10. The R/W circuit 12 supplies data to, and receives data from, the head 9 through a head amplifier (not shown). More precisely, the R/W circuit 12 converts data to be stored on the disk 10 to a write signal, which is supplied to the head 9. The R/W circuit 12 also receives a read signal read by the head 9 and demodulates the read signal. The head 9 is mounted on an actuator 19. The actuator 19 is driven as the MPU 14 performs a servo control, and moves the head 9 to a target position over the disk 10.

The disk 10 is rotated by a spindle motor 8 (in the direction indicated by arrow 130). On the disk 10, tracks 100 are provided, each is composed of a plurality of sectors, and servo data 110 is recorded. FIG. 2B shows the data format of each track 100. As shown in FIG. 2B, servo data 110 and data 120, both in units of long sectors, are alternately arranged at regular intervals in the track 100. The MPU 14 performs the servo control in accordance with the servo data 110 read by the head 9.

### [Data Transfer Control]

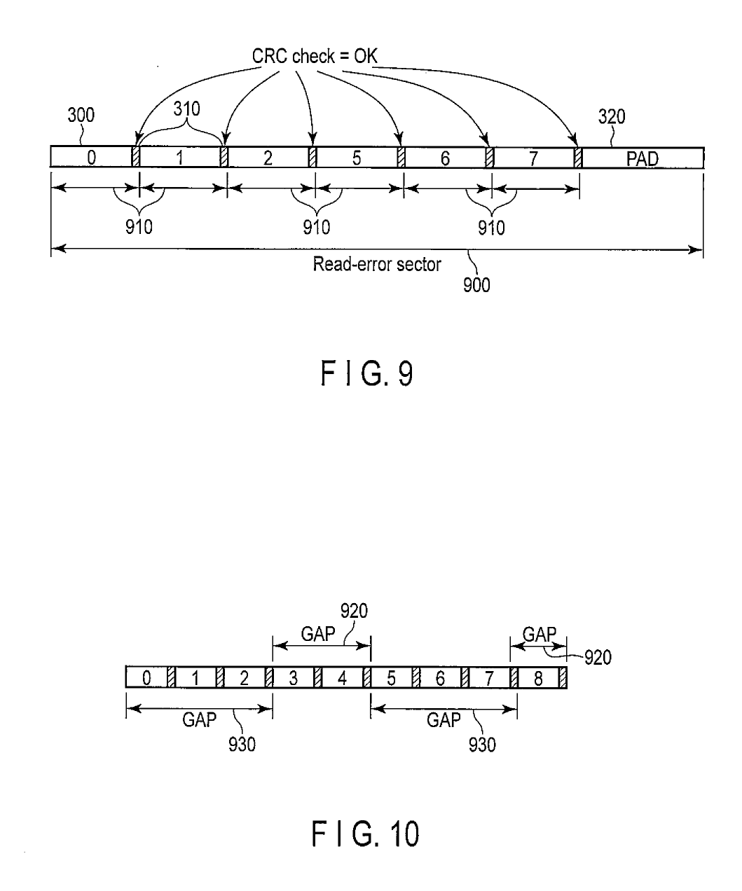

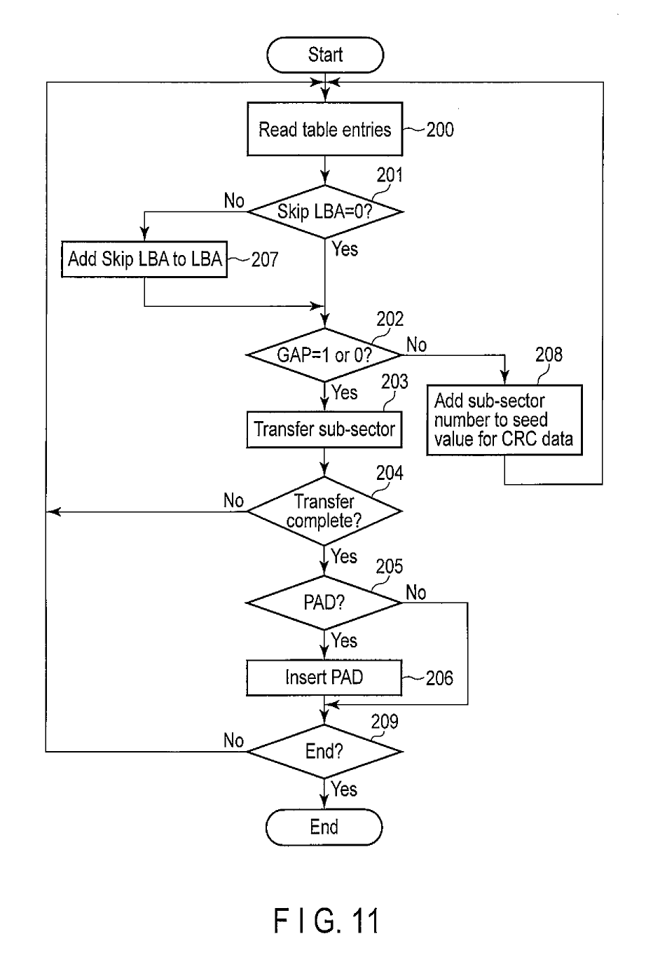

How the data transfer is controlled in this embodiment will be explained with reference to FIGS. 3 to 10 and also to the flowchart of FIG. 11.

FIG. 3 shows the state the write cache assumes when the data transferred from the host 20 is stored in the buffer memory 180. On receiving data 300 in units of sub-sectors (hereinafter referred to as sub-sector data in some cases), the host interface module 16 stores the data 300 in the buffer memory 180. Note that data unit 300(A), data unit 300(B), data unit 300(C) and data unit 300(D) are discontinuous.

In FIG. 3, data 310 are cyclic redundancy check (CRC) codes in units of sub-sectors. The host interface module 16 adds a CRC code 310 to any sub-sector data unit 300 it has received from the host 20, and stores the sub-sector data unit 300 in the buffer memory 180.

As a result, the buffer memory 180 stores not only long sector data, but also stores sub-sector data, i.e., partial data not as large as the long sector data (i.e., media sector data). That is, each of the data at the logic block addresses LBA (N−1), LBA (N+3) and LBA (N+4) lacks a part of the long sector (of, for example, 8-sub-sector size). By contrast, the data at the logic block addresses LBA (N), LBA (N+1) and LBA (N+2) have the long sector size.

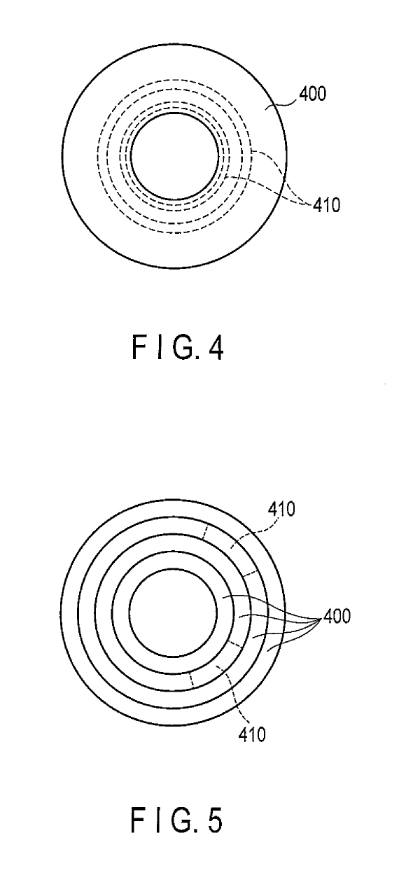

The data transfer controller 17 reads the long sector data at the logic block addresses LBA (N), LBA (N+1) and LBA (N+2) from the buffer memory 180 and transfer them via the R/W circuit 12 to the disk 10. The long sector data are thus written (over-written) in the ordinary recording area 400 that is provided on the disk 10, as is shown in FIG. 4 or FIG. 5.

On the other hand, the data at the logic block addresses LBA (N−1), LBA (N+3) and LBA (N+4) cannot be written in the ordinary recording area 400 provided on the disk 10, if they stay partial data in format. In order change the data in format, the RMW process is performed on the data as described above. The RMW process is better performed in the idling period of the disk drive 1. If the power supply to the disk drive 1 is cut in the idling period, however, the data stored in the buffer memory 180 will be lost before it has been written to the disk 10.

Hence, before the RMW process is performed, the data transfer controller 17 perform a control, first converting every sub-sector data stored in the buffer memory 180 to data of the long sector format and then recording (saving) this data temporarily in the save areas 410 provided on the disk 10. As shown in FIG. 4, the save areas 410 are set in units of tracks, each composed of any given number of tracks. Note that the ordinary recording area 400 is composed of many tracks. Alternatively, the save areas 410 may be set in units of long sectors if the ordinary recording area 400 is divided into zones as shown in FIG. 5.

The data transfer controller 17 uses such a table as shown in FIG. 7, to achieve the data transfer (writing) to the save areas 410. As seen from FIG. 7, each entry in the table consists of a buffer address (Address), a sub-sector ID flag (GAP), a last transfer ID flag (END), an additional LBA value (Skip LBA), number of reserved sectors (Reserved), and number of sectors (Num). The table is stored in the buffer memory 180, and the MPU 14 updates every entry in the table.

The buffer address (Address) represents the head address of a subsector to be transferred. The sub-sector

ID flag (GAP) is a flag that identifies the sub-sector data existing in the buffer memory 180. This flag is provided, because a sub-sector may exist outside the buffer memory 180 for a partial long sector, if any. The sub-sector ID flag (GAP) is used to update the seed value of the CRC code that should be added to a subsector, as will be described later.

The last transfer ID flag (END) is a flag that identifies the last sub-sector data to be transferred to a save area. This flag (END) is set in the entry containing the sub-sector valid for the last transfer, and is used to designate the position at which to insert invalid data, which will be described later. The additional LBA value (Skip LBA) represents LBAs added in the save areas before data is transferred to the save areas. The additional LBA value (Skip LBA) is used to write partial sub-sectors, all at one time. That is, the additional LBA value (Skip LBA) is added to the present LBA value, enabling the disk drive 1 to keep operating. The number of sectors (Num) represents the number of continuous sub-sectors stored in the buffer memory 180, which can be handed with one entry. That is, the number of sectors (Num) is the continuous sub-sectors per GAP, i.e., Num/GAP. The smallest number of sub-sectors the one entry can handle is one, and the largest number of sub-sectors the one entry can handle is one less than the number of sub-sectors in a long sector.

FIG. 8 shows a specific example of a table used to transfer (write) partial sub-sector data (LBA (N−1), LBA (N+3) and LBA (N+4)) to the save areas 410 provided on the disk 10. That is, a 4-sector data unit 300 (A) and a 3-sector data unit 300 (B) are retrieved, as sub-sectors corresponding to the LBA (N−1), from the table of FIG. 8. Further, a 3-sector data unit 300 (C) and a 3-sector data unit 300 (D) are retrieved, as sub-sector data corresponding to the LBA (N+3), from the table of FIG. 8. Still further, a 5-sector data unit 300 (D) is retrieved, as sub-sector data corresponding to the LBA (N+4), from the table of FIG. 8.

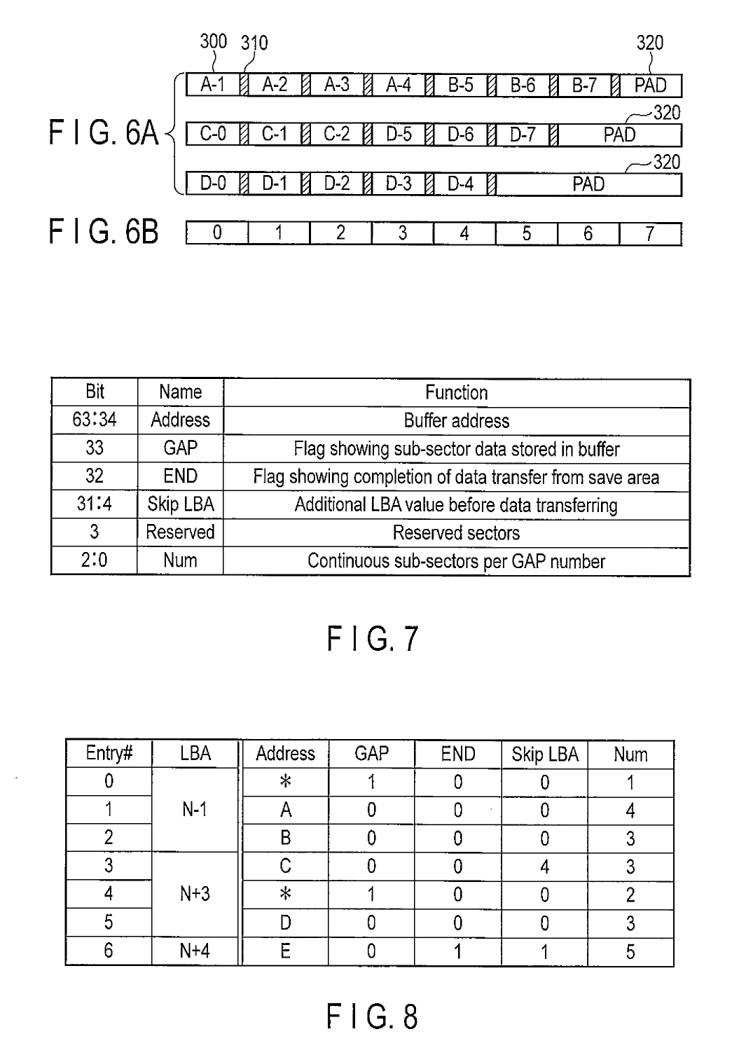

How the data transfer from the buffer memory 180 to a save area 410 of the disk 10 will be explained with reference to FIGS. 6A and 6B, FIG. 8 and the flowchart of FIG. 11.

To start the data transfer, the data transfer controller 17 refers to the table of FIG. 8, which is stored in the buffer memory 180, first reading the items of the first entry (#0) (Block 200). More precisely, the data transfer controller 17 acquires each item of, for example, the LBA (N−1) and a seed value (or initial value) for the CRC data to be added to a sub-sector.

As shown in FIG. 6A, the long sector format to be written in the data saving area 410 is a format composed of sub-sector data units 300 having sub-sector numbers (A-1, A-2, B-5, B-6, etc.), which are arranged in the order mentioned. Note that FIG. 6B shows the long sector format written in the ordinary recording area 400.

The data transfer controller 17 determines whether the LBA value (Skip LBA) added to the present LBA value is 0 or not (Block 201). If the addition LBA value (Skip LBA) is 0, the data transfer controller 17 determines, from the sub-sector ID flag (GAP), whether sub-sectors exist in the buffer memory 180 (GAP=0) or not (GAP=1) (Block 202). If the addition LBA value (Skip LBA) is not 0, partial sub-sectors are spaced apart as in the LBA (N+3) shown in FIG. 3. In this case, the data transfer controller 17 adds an LBA value (Skip LBA=4) to the present LBA value, making it possible to transfer sub-sectors continuously (Block 207, if NO in Block 201).

If the sub-sector ID flag (GAP) is 1 (GAP=1), no sub-sectors exist in the buffer memory 180. In this case, the data transfer controller 17 adds the sub-sector number (Num=1) to the seed value for the CRC data (Block 208, if NO in Block 202). The number added is a blank part that is indicated as a buffer address (Address=*) for the LBA (N−1) shown in FIG. 3.

Next, the data transfer controller 17 reads the items of the second entry (#1) shown in FIG. 8 (Block 200). If the additional LBA value (Skip LBA) is 0 and if the sub-sector ID flag (GAP) is 0 (GAP=0), continuous sub-sectors (A and B) exist in the buffer memory 180. In this case, the data transfer controller 17 transfers the sub-sectors (A and B) (Block 203).

As transmitting sub-sectors, the data transfer controller 17 generates CRC data 310 for each sub-sector. If the sub-sector ID flag (GAP) is 1 (GAP=1), continuous sub-sectors (A and B) do not exist in the buffer memory 180. In this case, the seed value of the CRC data to be added is updated (Block 208). That is, partial sub-sectors (C and D) are spaced apart as in the LBA (N+3) shown in FIG. 3.

The data transfer controller 17 then determines whether the sub-sectors have been transferred (Block 204). If the sub-sectors are found transferred, the data transfer controller 17 calculates the size of invalid data (PAD) 320 required for constituting a long sector format (Block 205, if YES in Block 204). The data transfer controller 17 inserts invalid data (PAD) 320 of the size calculated as shown in FIG. 6A (Block 206). As a result, the sub-sector data belonging to the LBA (N−1) shown in FIG. 3 is transferred and written in the save area 410. That is, data of long sector format is recorded in the save area 410 as shown in FIG. 6A, the data composed of sub-sector units 300 arranged in the order of sub-sector numbers (A-1, A-2, A-3, A-4, B-5, B-6 and B-7) and invalid data PAD 320.

The data transfer controller 17 repeats the process of transferring sub-sector data for remaining entries #2 to #6. When the last transfer ID flag (END) is detected, the data transfer controller 17 determines that the data transfer from the buffer memory 180 to the save area 410 is complete (Block 209).

Thus, the CRC data 310 can be added to any one of the sub-sector data units 300 existing as partial data in the buffer memory 180. Moreover, sub-sector data of the format including invalid data (PAD) 320 can be transferred to (saved in) the save area 410 provided on the disk 10. In other words, data stored in the buffer memory, in units of sub-sectors, can be reliably saved before the RMW process is performed. The sector format written in the data saving area 410 has the same size as the long sector format (see FIGS. 6A and 6B).

The data of the long sector format remain saved in the save area 410 until the HDC 13 performs the RMW process. This greatly reduces the possibility that the sub-sector data stored in the buffer memory 180 is lost before being written to the disk 10, because the power supply to the disk drive 1, for example, is cut before the sub-sector data is written to the disk 10. The HDC 13 performs the RMW process during the idling period of the disk drive 1, first reading data of the long sector format from the save area 410 into the buffer memory 180, then merging this data with the data stored in the ordinary reads, and finally writing the merged data to the disk 10.

In this embodiment, the sector format in which data is transferred to the save area 410 has the same size as the ordinary long sector format. Therefore, the save area 410 can be provided in each track or in each zone as shown in FIGS. 4 and 5. In addition, spare areas for use in place of defective areas can be used as save areas 410.

If the save areas differ in format from the ordinary sectors, the R/W controller 15 needs to perform a transfer switching process, thereby to change various parameters set in a register, such as sector pulse. In this embodiment, the save areas have the same format as the ordinary sectors, and the /W controller 15 need not perform a transfer switching process. This can decrease the overhead of the R/W controller 15.

In this embodiment, CRC data 310 is added to each sub-sector in the sector format transferred to any save area 410. If the invalid data (PAD) 320, for example, has a defective part, the long sector holding the invalid data (PAD) 320 will become a read-error sector 900. In this embodiment, such a read-error in any sub-sector can be detected from the CRC data 310. Hence, normal data reading can be completed by performing an error correction process on every sub-sector 910.

The host interface module 16 adds CRC data to any data transferred from the host 20, and the data now including the CRC data is stored in the buffer memory 180. Before each sub-sector data read from the buffer memory 180 is written in a save area 410, new CRC data may be added to the sub-sector data or the CRC data added to the sub-sector data by the host interface module 16 may be changed.

Moreover, the entries in the tables of FIGS. 7 and 8 can be used as they are, to read data from any save area 410 into the buffer memory 180 and to merge the data with the data stored in an ordinary recording area 400 (in the RMW process).

To be more specific, the data read from any save area 410 is stored in units of sectors, the buffer memory 180, spacing the data units for the respective table entries, by GAP 920, as shown in FIG. 10. If data is read from any ordinary recording area 400, only the data identified with the GAP 930 of any entry in the table may be stored in the buffer memory 180.

Therefore, the data recorded in any save area 410 can be merged with the data recorded in any ordinary area 400 in the buffer memory 180, by using the tables of FIGS. 7 and 8, without necessity of preparing new tables.

In this embodiment, the RMW process is performed in the buffer memory 180 that is a DRAM. Nonetheless, the RMW process may be performed in the SRAM included in the memory 18.

The data storage apparatus 1 according to this embodiment is not limited to a disk drive. Rather, it may be a solid-state drive (SSD) having flash memories used as a nonvolatile storage medium 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A data storage control apparatus comprising:
an interface module configured to receive first data, in specific units, from a host and to store the first data in a buffer memory; and
a controller configured to generate second data from the first data stored in the buffer memory and to perform a control to write the second data to a nonvolatile storage medium,
wherein the controller is configured to generate the second data of a second format having the same size as the first format of the data stored in an ordinary recording area provided at the nonvolatile storage medium, and comprising a plurality of units of the first data and invalid data, and to perform a control to write the second data in a save area provided on the nonvolatile storage medium.

2. The apparatus of claim 1, wherein the controller is configured to use a table information for writing the second data in the save area, thereby merging the data read from the save area with the data read from the ordinary recording area, to generate data of the first format, and to write the data of the first format back to the ordinary recording area.

3. The apparatus of claim 1, wherein the controller is configured to add an error checking code data to the first data before the second data is written in the save area.

4. The apparatus of claim 3, wherein the controller is configured to perform an error checking process on the first data, by using the error checking code data, with respect to the data read from the save area.

5. The apparatus of claim 1, wherein the controller is configured to generate the second data of a long sector format comprising a plurality of sectors of the first data that is composed of predetermined sector units.

6. The apparatus of claim 5, wherein the controller is configured to use a table information for writing the second data of the long sector format in the save area, thereby performing a read modify write process of merging the data read from the save area with the data read from the ordinary recording area, thus generating data of the long sector format.

7. A data storage apparatus comprising:
a data storage control apparatus according to claim 1; and
a nonvolatile storage medium comprising a disk.

8. A data storage apparatus comprising:
a data storage control apparatus according to claim 1; and
a nonvolatile storage medium comprising a flash memory.

9. A method of data write control, for use in a data storage apparatus having a nonvolatile storage medium, the method comprising:
receiving first data, in specific units, from a host, and storing first the data in a buffer memory; and
generating second data of a second format having the same size as the first format of the data stored in an ordinary recording area provided at the nonvolatile storage medium, and comprising a plurality of units of the first data and invalid data; and
writing the second data in a save area provided on the nonvolatile storage medium.

10. The method of claim 9, further comprising:
using a table information for writing the second data in the save area, thereby merging the data read from the save area with the data read from the ordinary recording area;
generating data of the first format; and
writing the data of the first format back to the ordinary recording area.

11. The method of claim 9, further comprising:
adding an error checking code data to the first data before the second data is written in the save area.

12. The method of claim 9, further comprising:
performing an error checking process on the first data, by using the error checking code data, with respect to the data read from the save area.

13. The method of claim 9, further comprising:
generating the second data of a long sector format comprising a plurality of sectors of the first data that is composed of predetermined sector units.

14. The method of claim 13, further comprising:
using a table information for writing the second data of the long sector format in the save area, thereby performing a read modify write process of merging the data read from the save area with the data read from the ordinary recording area, thus generating data of the long sector format.
